(19) United States
(12) Patent Application Publication
(10) Pub. No.: US 2006/0114527 A1
(43) Pub. Date: Jun. 1, 2006

(54) Image pickup apparatus

(75) Inventors: Taketo Tsukioka, Tokyo (JP); Akira Ueno, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Olympus Corporation, Tokyo (JP)

(21) Appl. No.: 11/288,523

(22) Filed: Nov. 29, 2005

(30) Foreign Application Priority Data
Nov. 30, 2004 (JP) 2004-346439

(51) Int. Cl. G03F 3/08

(52) U.S. Cl. 358/519

(57) ABSTRACT

An image pickup apparatus 200 includes an image pickup means 220, a tone conversion means 250, and conversion characteristic determination means 260. The tone conversion means 250 applies tone conversion processing to image data that the image pickup means 220 for acquiring image data of a subject has acquired using tone conversion characteristic T′ (v) differing depending on the pixel position. The conversion characteristic determination means 260 determines the tone conversion characteristic T′ (v) depending on an image pickup condition that has been set in the image pickup means 220 for acquisition of the digital image data.

### TECHNICAL FIELD

The present invention relates to an image pickup apparatus and more particularly to an image pickup apparatus that performs tone conversion on image data of a picked up subject.

### BACKGROUND ART

In recent years, various inventions related to a process of favorably correcting the tone of an image have been made. For example, a highly flexible technique that performs tone conversion while changing tonal characteristics of an image depending on the pixel position in the image (refer to, for example, Jpn. Pat. Appln. Laid-Open Publication No. 2002-94998, Japanese Patent No. 3465226) and a technique capable of restricting tonal characteristics to prevent an image to be obtained as a result of tone conversion from being artificial (refer to, for example, PCT Application Laid-Open No. 2004-530368) have been proposed.

Further, a tone conversion technique in an image pickup system has also been proposed. For example, a technique disclosed in Jpn. Pat. Appln. Laid-Open Publication No. 2003-46778 applies tone conversion to a picked up image in such a manner to emphasize particular parts in the image depending on the image pickup condition.

However, in the prior arts such as Publication No. 2002-94998 and Japanese Patent No. 3465226, there is no description as to a configuration best suited to the case where such an advanced tone conversion technique is implemented in an image pickup apparatus such as a digital camera, or there is no idea of increasing capability of the image pickup apparatus by making full use of the features of the tone conversion technique. Further, in the prior art such as Publication No. 2003-46778, although it is possible to perform tone conversion in such a manner to emphasize particular parts in an image depending on the image pickup condition, tone conversion for the parts other than the particular parts could not be performed to such a degree as to satisfy a user in some cases.

The present invention has been made in view of the above problems in the prior arts, and an object thereof is to provide an image pickup apparatus having high tone conversion capability.

### DISCLOSURE OF INVENTION

To achieve the above object, the image pickup apparatus according to claim 1 is characterized by comprising: an image pickup means for acquiring image data of a subject; a tone conversion means for applying tone conversion processing to the image data acquired by the image pickup means using different tone conversion characteristics depending on the pixel position; and a conversion characteristic determination means for determining the tone conversion characteristic depending on an image pickup condition that has been set in the image pickup means for acquisition of the digital image data. According to the image pickup apparatus as claimed in claim 1, tone conversion can be performed using different tone conversion characteristics depending on the pixel position. Further, the tone conversion characteristic can be determined depending on the image pickup condition set at the image pickup time.

In the image pickup apparatus according to claim 1, the image pickup apparatus according to claim 2 is characterized in that the conversion characteristic determination means determines a degree at which the tone conversion characteristic for each pixel varies depending on the pixel position based on the image pickup condition that has been set for acquisition of the digital image data.

In the image pickup apparatus according to claim 2, the image pickup apparatus according to claim 3 is characterized in that the image pickup condition includes conditions related to auto-focus, and the conversion characteristic determination means determines a degree at which the tone conversion characteristic for each pixel varies depending on the pixel position based on the conditions related to auto-focus. According to the image pickup apparatus as claimed in claim 3, a degree at which the tone conversion characteristic varies depending on the pixel position is determined based on the conditions related to auto-focus, which can reflect the conditions related to auto-focus on the tone conversion processing.

In the image pickup apparatus according to claim 3, the image pickup apparatus according to claim 4 is characterized in that the conversion characteristic determination means determines the tone conversion characteristic such that a degree at which the tone conversion characteristic for each pixel differs becomes large depending on the pixel position as the area to be focused on becomes narrower in the conditions related to auto-focus. According to the image pickup apparatus as claimed in claim 4, in the case where focusing is performed on the narrower area in the image, it is possible to achieve optimal local contrast in the range in focus.

In the image pickup apparatus according to claim 2, the image pickup apparatus according to claim 5 is characterized in that the image pickup condition includes various types of subject modes, the image pickup means picks up an image of a subject in one subject mode that has been designated from the outside to acquire the image data, and the conversion characteristic determination means determines a degree at which the tone conversion characteristic for each pixel varies depending on the pixel position based on the one subject mode that has been designated from the outside. According to the image pickup apparatus as claimed in claim 5, a degree at which the tone conversion characteristic varies depending on the pixel position is determined based on the subject modes, which can reflect the subject modes on the tone conversion processing.

In the image pickup apparatus according to claim 5, the image pickup apparatus according to claim 6 is characterized in that the conversion characteristic determination means sets the upper limit of a degree at which the tone conversion characteristic for each pixel varies depending on the pixel position based on the type of the subject mode and determines a degree at which the tone conversion characteristic for each pixel varies depending on the pixel position based on the upper limit. According to the image pickup apparatus as claimed in claim 6, the upper limit of a degree at which the tone conversion characteristic for each pixel varies depending on the pixel position is set, thereby preventing the result of the tone conversion processing from greatly differing depending on the pixel position.

In the image pickup apparatus according to claim 2, the image pickup apparatus according to claim 7 is characterized in that the tone conversion means calculates the tone conversion characteristic based on a histogram that represents the distribution of pixel values of pixels to be subjected to the tone conversion processing and pixels existing in a predetermined range around the target pixels, and the conversion characteristic determination means determines the size of the predetermined range to thereby determine a degree at which the tone conversion characteristic for each pixel varies depending on the pixel position. According to the image pickup apparatus as claimed in claim 7, the tone conversion characteristic is calculated based on a histogram that represents the distribution of pixel values of pixels to be subjected to the tone conversion processing and pixels existing in a predetermined range around the target pixels, and the size of the predetermined range is determined to determine a degree at which the tone conversion characteristic for each pixel varies depending on the pixel position, thereby making it easy to determine a degree at which the tone conversion characteristic differs depending on the pixel position.

In the image pickup apparatus according to claim 3, the image pickup apparatus according to claim 8 is characterized in that the tone conversion means calculates the tone conversion characteristic based on a histogram that represents the distribution of pixel values of pixels to be subjected to the tone conversion processing and pixels existing in a predetermined range around the target pixels, and the conversion characteristic determination means determines the size of the predetermined range to thereby determine a degree at which the tone conversion characteristic for each pixel varies depending on the pixel position.

In the image pickup apparatus according to claim 5, the image pickup apparatus according to claim 9 is characterized in that the tone conversion means calculates the tone conversion characteristic based on a histogram that represents the distribution of pixel values of pixels to be subjected to the tone conversion processing and pixels existing in a predetermined range around the target pixels, and the conversion characteristic determination means determines the size of the predetermined range to thereby determine a degree at which the tone conversion characteristic for each pixel varies depending on the pixel position.

In the image pickup apparatus according to claim 1, the image pickup apparatus according to claim 10 is characterized in that the tone conversion means has a function of approximating the tone conversion characteristic to reference tone conversion characteristic that has been previously defined, and the conversion characteristic determination means determines a degree at which the tone conversion characteristic is approximated to the reference tone conversion characteristic depending on the image pickup condition to thereby determine the tone conversion characteristic. As described above, a degree at which the tone conversion characteristic is approximated to the reference tone conversion characteristic is determined depending on the image pickup condition, thereby realizing optimal tone conversion processing according to the image pickup condition.

In the image pickup apparatus according to claim 2, the image pickup apparatus according to claim 11 is characterized in that the tone conversion means has a function of approximating the tone conversion characteristic to reference tone conversion characteristic that has been previously defined, and the conversion characteristic determination means determines a degree at which the tone conversion characteristic is approximated to the reference tone conversion characteristic depending on the image pickup condition to thereby determine the tone conversion characteristic.

In the image pickup apparatus according to claim 3, the image pickup apparatus according to claim 12 is characterized in that the tone conversion means has a function of approximating the tone conversion characteristic to reference tone conversion characteristic that has been previously defined, and the conversion characteristic determination means determines a degree at which the tone conversion characteristic is approximated to the reference tone conversion characteristic depending on the image pickup condition to thereby determine the tone conversion characteristic.

In the image pickup apparatus according to claim 5, the image pickup apparatus according to claim 13 is characterized in that the tone conversion means has a function of approximating the tone conversion characteristic to reference tone conversion characteristic that has been previously defined, and the conversion characteristic determination means determines a degree at which the tone conversion characteristic is approximated to the reference tone conversion characteristic depending on the image pickup condition to thereby determine the tone conversion characteristic.

In the image pickup apparatus according to claim 1, the image pickup apparatus according to claim 14 is characterized in that the tone conversion means includes a first conversion processing section that applies tone conversion processing to the image data and a second conversion processing section that applies tone conversion processing corresponding to the pixel position to an output of the first conversion processing section, and the conversion characteristic determination means determines tone conversion characteristic to be used in tone conversion processing performed by the first conversion processing section depending on the image pickup condition. According to the image pickup apparatus as claimed in claim 14, the second conversion processing section performs image conversion using tone conversion characteristic differing depending on the pixel position after the first conversion processing section has performed processing for image data using tone conversion characteristics corresponding to the set image pickup condition. That is, it is possible to perform image conversion based on the pixel position after image conversion based on the image pickup condition.

In the image pickup apparatus according to claim 14, the image pickup apparatus according to claim 15 is characterized in that the first conversion processing section performs tone conversion processing for respective pixels constituting the subject image using common tone conversion characteristic, and the conversion characteristic determination means changes the common tone conversion characteristic set in the first conversion processing section depending on the image pickup condition. According to the image pickup apparatus as claimed in claim 15, the second conversion processing section performs image conversion using tone conversion characteristic differing depending on the pixel position after the first conversion processing section performs processing for image data for respective pixels using common tone conversion characteristic corresponding to the image pickup condition. That is, it is possible to perform image conversion based on the pixel position after tone conversion for respective pixels using common tone conversion characteristic corresponding to the image pickup condition.

In the image pickup apparatus according to claim 15, the image pickup apparatus according to claim 16 is characterized in that the image pickup condition includes an exposure correction condition that defines, an exposure correction level, and the conversion characteristic determination means changes the tone conversion characteristic depending on the exposure correction condition. According to the image pickup apparatus as claimed in claim 16, the second conversion processing section performs image conversion using tone conversion characteristic differing depending on the pixel position after the first conversion processing section performs processing for image data for respective pixels using common tone conversion characteristic corresponding to the exposure correction condition. That is, it is possible to perform image conversion based on the pixel position after tone conversion for respective pixels using common tone conversion characteristic corresponding to the exposure correction condition.

In the image pickup apparatus according to claim 15, the image pickup apparatus according to claim 17 is characterized in that the image pickup condition includes an exposure condition which is based on restriction on the shutter speed, and the conversion characteristic determination means changes the tone conversion characteristic depending on the exposure condition. According to the image pickup apparatus as claimed in claim 17, the second conversion processing section performs image conversion using tone conversion characteristic differing depending on the pixel position after the first conversion processing section performs processing for image data for respective pixels using common tone conversion characteristic corresponding to the exposure condition which is based on restriction on the shutter speed. That is, it is possible to perform image conversion based on the pixel position after tone conversion for respective pixels using common tone conversion characteristic corresponding to the exposure condition which is based on restriction on the shutter speed.

In the image pickup apparatus according to claim 1, the image pickup apparatus according to claim 18 is characterized in that the image pickup condition includes an exposure correction condition that defines an exposure correction level, and the conversion characteristic determination means changes the tone conversion characteristic depending on the exposure correction condition.

In the image pickup apparatus according to claim 1, the image pickup apparatus according to claim 19 is characterized in that the image pickup condition includes an exposure condition which is based on restriction on the shutter speed, and the conversion characteristic determination means changes the tone conversion characteristic depending on the exposure condition.

### BRIEF DESCRIPTION OF DRAWINGS

FIG. 1 is a block diagram showing a functional configuration of an image pickup apparatus according to a first embodiment of the present invention;

FIG. 2 is a view for explaining tone conversion characteristics obtained depending on the exposure condition;

FIG. 3 is a view for explaining tone conversion characteristics obtained depending on the condition of camera shake prevention function;

FIG. 4 is a view for explaining space-variant tone conversion processing;

FIG. 5 is a flowchart for explaining a process flow in the first embodiment of the present invention;

FIG. 6 is a block diagram showing a functional configuration of an image pickup apparatus according to a second embodiment of the present invention;

FIG. 7 is a view for explaining respective modes of an auto-focus function;

FIG. 8 is a view for explaining values a and a relative to respective image pickup conditions;

FIG. 9 is a view for explaining the flow of processing in the second embodiment of the present invention;

FIG. 10 is a view for explaining the flow of processing in the second embodiment of the present invention; and

FIG. 11 is a block diagram showing a functional configuration of an image pickup apparatus according to a third embodiment of the present invention.

### BEST MODE FOR CARRYING OUT THE INVENTION

Embodiments of the present invention will be described below with reference to the accompanying drawings.

### First Embodiment

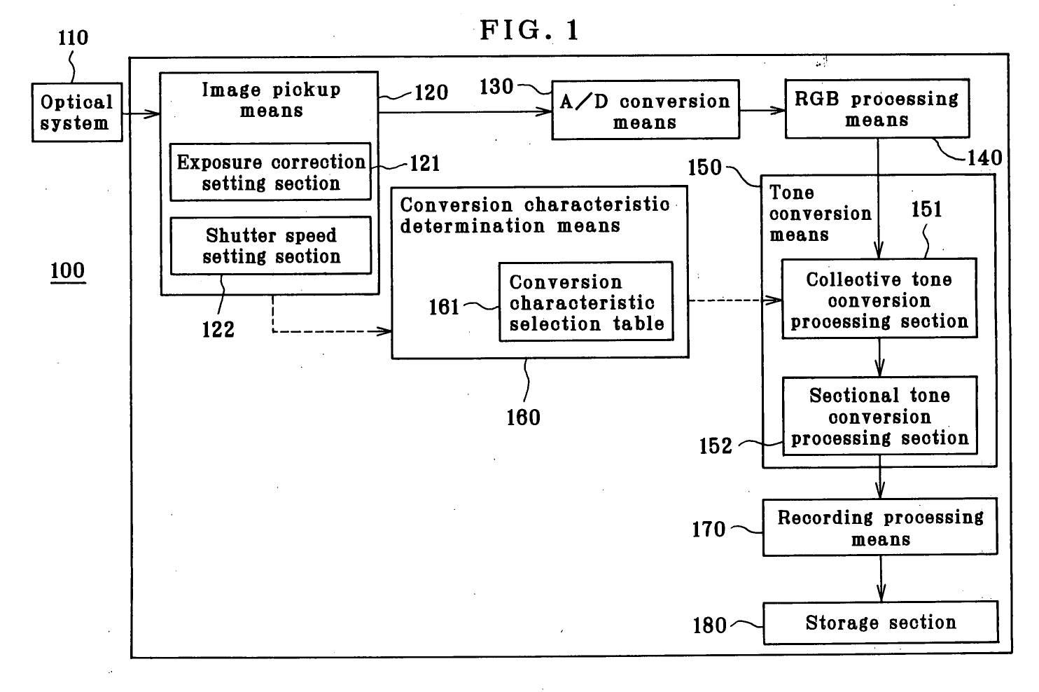

A first embodiment of an image pickup apparatus according to the present invention will be described with reference to FIG. 1 to FIG. 5. An image pickup apparatus exemplified here may be a digital still camera, a microscope, or an image pickup apparatus connected to an endoscope.

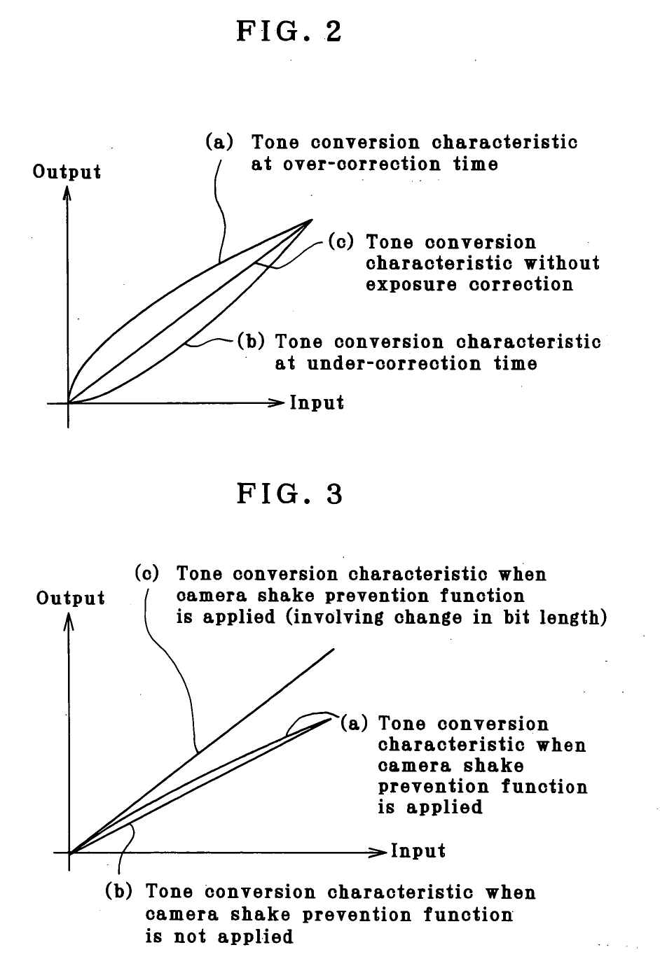

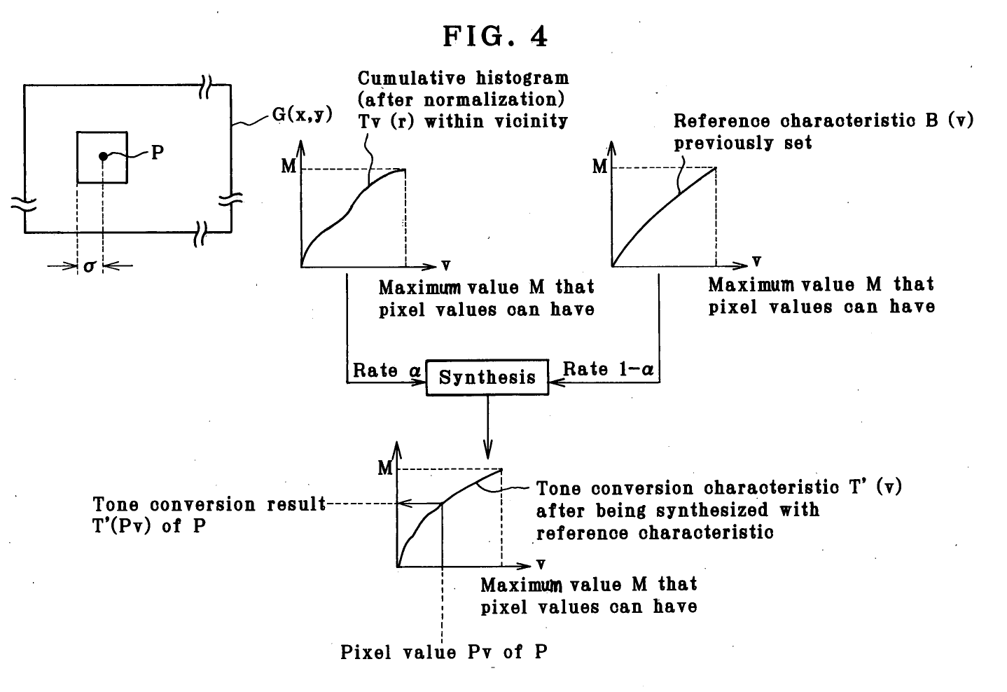

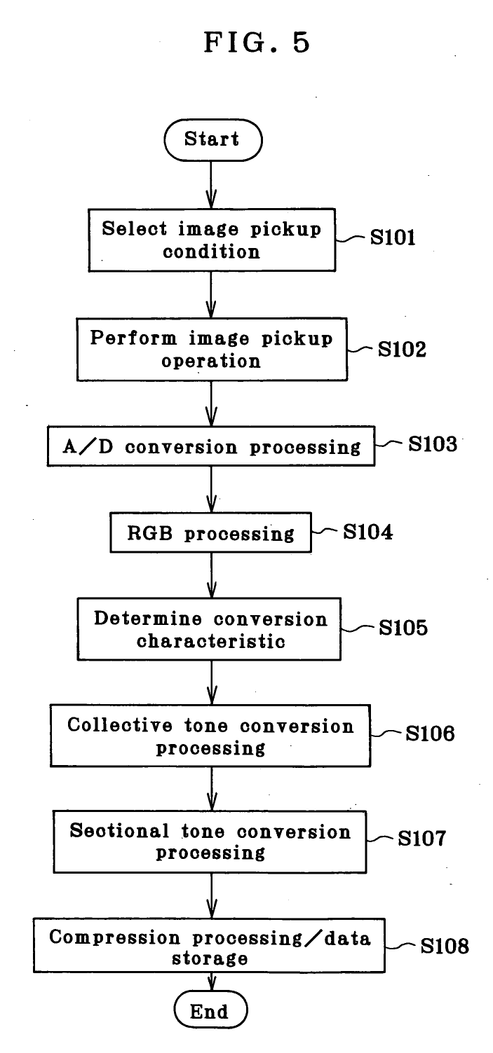

FIG. 1 is a block diagram showing a functional configuration of an image processing apparatus 100. FIG. 2 is a view for explaining tone conversion characteristics obtained depending on the exposure condition. FIG. 3 is a view for explaining tone conversion characteristics obtained depending on the condition of camera shake prevention function. FIG. 4 is a view for explaining space-variant tone conversion processing. FIG. 5 is a flowchart for explaining a process flow in the first embodiment. As shown in FIG. 1, an image pickup apparatus 100 includes an optical system 110, an image pickup means 120, an A/D conversion means 130, an RGB processing means 140, a tone conversion means 150, a conversion characteristic determination means 160, a recording processing means 170, and a storage section 180.

The optical system 110 is a lens unit constituted by a plurality of lenses. The image pickup means 120 includes an image pickup device such as a CCD or CMOS. In picking up a subject image, the image pickup means 120 converts the subject image focused by the optical system 110 into an electrical image signal. The image pickup means 120 further includes an exposure correction setting section 121, a shutter speed setting section 122, and a user interface (not shown) for a user to select the exposure correction condition and whether or not to apply camera shake prevention function. The exposure correction setting section 121 and shutter speed setting section 122 receive user's operation through the user interface and set image pickup condition such as the exposure correction condition or “application” or “not application” of camera shake prevention function.

A user can increase or reduce the brightness on an image when he or she picks up the image in accordance with the level of the exposure correction condition. The exposure correction condition is set, in accordance with the user's selection, in the exposure correction setting section 121. Upon receiving the user's selection indicating “application” of camera shake prevention function, the shutter speed setting section 122 set a faster shutter speed to reduce the blurring of a subject at the time of image pickup to a required level. The exposure correction setting section 121 and shutter speed setting section 122 hold the set image pickup conditions (exposure correction condition, “application” or “not application” of camera shake prevention function, and the like).

The A/D conversion means 130, such as an A/D converter, converts an analog output signal of the image pickup means 120 into a digital signal to generate image data of image pickup time. The RGB processing means 140 generates image data of three colors (B, G and R) based on the output from the A/D conversion means 130. The image data includes data of pixel values that a large number of pixels arranged in a predetermined pattern, for example, in a matrix form respectively have. The pixel values of the respective pixel are expressed in tones suitable for being processed by a computer. In the present embodiment, each pixel value is expressed in 12-bit tone at the time when the image data is output from the RGB processing means 140.

That is, after the image pickup apparatus 100 has received user's selection of the image pickup condition (exposure correction condition or “application” or “not application” of camera shake prevention function) and user's operation of a shutter button (not shown) of the image pickup apparatus 100, the optical image of a subject is focused on the image pickup device (CCD or CMOS) of the image pickup means 120 by the optical system 110, and the selected image pickup condition (subject mode) is stored in the exposure correction setting section 121 and shutter speed setting section 122.

After allowing the image pickup device to convert the optical image into an electrical signal, the image pickup means 120 outputs the electrical signal to the A/D conversion means 130. The A/D conversion means 130 converts the electrical signal into digital data and outputs it to the RGB processing means 140. The RGB processing means 140 applies processing to the input digital data to generate image data of three colors (R, G, and B) and outputs it to the tone conversion means 150. The tone conversion means 150 performs tone conversion for the image data output from the RGB processing means 140. The tone conversion means 150 has a collective tone conversion processing section 151 and a sectional tone conversion processing section 152. The collective tone conversion processing section 151 and sectional tone conversion processing section 152 correspond to a first conversion processing section and second conversion processing section of the present invention, respectively. In the following, the processing performed in the collective tone conversion processing section 151 and sectional tone conversion processing section 152 will be described.

The collective tone conversion processing section 151 performs collective tone conversion processing for the pixel values of respective pixels constituting the image data obtained from the RGB processing means 140. In the collective tone conversion processing, tone conversion processing is performed for all the pixels constituting the picked up subject image according to common tone conversion characteristic. In the present embodiment, the collective tone conversion processing is performed based on the image pickup condition used at the time when the subject is picked up by the image pickup means 120. Examples of the image pickup condition include the abovementioned exposure correction condition and “application” or “not application” of camera shake prevention function (restriction on shutter speed).

In the collective tone conversion processing performed based on the exposure correction condition, the tone conversion is performed according to the tone conversion characteristics as shown in, for example, FIG. 2. The tone conversion characteristic represented by a curve (a) of FIG. 2 is one to be applied when an image pickup is performed with over-correction set as the exposure correction condition and is previously stored in the collective tone conversion processing section 151. The term “over-correction” as used here is an image pickup condition that serves to improve tone reproduction of dark part obtained when image pickup operation has been performed with the brightness on an image increased, relative to the case where exposure correction is not applied.

The tone conversion characteristic represented by a curve (b) of FIG. 2 is one to be applied when an image pickup is performed with under-correction set as the exposure correction condition and is previously stored in the collective tone conversion processing section 151. The term “under-correction” as used here is an image pickup condition that serves to improve tone reproduction of bright part obtained when image pickup operation has been performed with the brightness on an image reduced, relative to the case where exposure correction is not applied.

The tone conversion characteristic represented by a curve (c) of FIG. 2 is one to be applied when an image pickup is performed without the setting of both over-correction and under-correction as the exposure correction condition and is previously stored in the collective tone conversion processing section 151.

Various types of tone conversion characteristics as represented by the curves (a) and (b) of FIG. 2 are previously stored in the collective tone conversion processing section 151 in accordance with the number of exposure correction conditions. The reason that such pre-processing is required at the time of exposure correction time is as follows. In the tone conversion processing that adaptively sets tone characteristics according to the type of an image like space-variant tone conversion to be described later, an overall dark image is made brighter and an overall bright image is made darker, in general. Therefore, change in the brightness obtained as a result of the exposure correction is less than expected. Thus, user's intention at the time of image pickup operation cannot be reflected in the processing result. To cope with this problem, in the present embodiment, space variant tone conversion is performed after the pre-processing has been applied to correct an image in such a manner as to make the whole image darker at the under-correction time and make the whole image brighter at the over-correction time so that change in the brightness essentially caused by exposure correction occurs more prominently than the case where only the space-variant tone conversion is performed.

In the collective tone conversion processing performed according to exposure condition based on application or not application of camera shake prevention function (restriction on shutter speed), the tone conversion is performed according to the tone conversion characteristics as shown in, for example, FIG. 3. The tone conversion characteristic represented by a curve (a) of FIG. 3 is one to be applied to the image pickup condition in which a faster shutter speed is set to suppress the blurring of a subject at the time of image pickup and is previously stored in the collective tone conversion processing section 151. At the image pickup time, shutter speed is set faster than a predetermined level so that the blurring of a subject at the time of image pickup is suppressed in some cases. In the case where the restriction on shutter speed is made as described above, underexposure may occur. The tone conversion characteristic represented by the curve (a) of FIG. 3 is one to be applied to the case where image pickup operation is performed under the condition that restriction on the shutter speed causes underexposure.

The tone conversion characteristic represented by a curve (b) of FIG. 3 is one to be applied to the image pickup condition in which underexposure does not occur and is previously stored in the collective tone conversion processing section 151. Here, the curve (a) of FIG. 3 shows a case where the bit length is not changed before and after the tone conversion. In the case where it is necessary to change the bit length before and after the tone conversion, the tone conversion characteristic as represented by a curve (c) of FIG. 3 previously stored in the collective tone conversion processing section 151 may be applied.

The conversion characteristic determination means 160 includes a conversion characteristic selection table 161, in which correspondences between the image pickup conditions and tone conversion characteristics to be applied to the image pickup conditions are stored. Assuming that the image pickup condition includes the above exposure correction conditions and exposure condition based on the restriction on shutter speed, the following correspondences are stored in the conversion characteristic selection table 161 of the conversion characteristic determination means 160.

(1) Tone conversion characteristic represented by the curve (a) of FIG. 2 is related to the image pickup condition in which over-correction has been set as the exposure correction condition.

(2) Tone conversion characteristic represented by the curve (b) of FIG. 2 is related to the image pickup condition in which under-correction has been set as the exposure correction condition.

(3) Tone conversion characteristic represented by the curve (c) of FIG. 2 is related to the image pickup condition in which both over-correction and under-correction are not set as the exposure correction condition.

(4) Tone conversion characteristic represented by the curve (a) of FIG. 3 is related to the image pickup condition in which restriction on the shutter speed causes underexposure. However, in the case where it is necessary to change the bit length before and after the tone conversion performed by the collective tone conversion processing section 151, tone conversion characteristic represented by the curve (c) of FIG. 3 is related to the above image pickup condition.

(5) Tone conversion characteristic represented by the curve (b) of FIG. 3 is related to the image pickup condition in which underexposure does not occur.

The conversion characteristic determination means 160 refers to the conversion characteristic selection table 161 and determines, based on the image pickup condition set at the time when the image pickup means 120 picks up a subject, the tone conversion characteristic to be applied to the image pickup condition. Since the image pickup conditions (exposure correction condition, application or not application of camera shake prevention function, and the like) are stored in the exposure correction setting section 121 and shutter speed setting section 122 at the image pickup time, the tone conversion characteristic to be applied is determined based on the stored image pickup conditions. The conversion characteristic determination means 160 instructs the collective tone conversion processing section 151 to perform tone conversion processing according to the determined tonal characteristic. The collective tone conversion processing section 151 performs tone conversion processing according to the determined tone conversion characteristic, as instructed by the conversion characteristic determination means 160. That is, the conversion characteristic determination means 160 determines tone conversion characteristic corresponding to the image pickup condition, and the collective tone conversion processing section 151 performs tone conversion processing according to the determined tone conversion characteristic.

The sectional tone conversion processing section 152 performs space-variant tone conversion processing based on the image data processed by the collective tone conversion processing section 151. In the space-variant tone conversion processing, tone conversion processing for respective pixels is performed based on the tone conversion characteristics corresponding to the positions of the pixels. As the space-variant tone conversion processing performed in the sectional tone conversion processing section 152, various types of space-variant tone conversions as disclosed in Jpn. Pat. Appln. Laid-Open Publication No. 2002-94998, Japanese Patent No. 3465226, and Jpn. Pat. Appln. Laid-Open Publication No. 7-203330 are available.

In the present embodiment, space-variant tone conversion processing is performed as shown in FIG. 4. Firstly, a cumulative histogram H of pixel values of respective pixels existing in the range of σ around pixel P=(px, py) in G-component input image G (x, y) of an RGB color image represented by a set of pixels that are arranged in a matrix form on x-y plane is produced. The obtained cumulative histogram H is normalized so that the maximum value thereof becomes maximum value M (for example, 255 (in the case of 8-bit data)) that the pixel values in the input image G (x, y) component can have to thereby obtain tone conversion characteristic T (v), where v is an integer number from 0 to M-1.

Next, T (v) and reference tone conversion characteristic B (v) that has been previously set are synthesized at a rate of a to produce new tone conversion characteristic T′ (v) represented by the following (numeral 1), where v is an integer number from 0 to M-1 as described above. The reference tone conversion characteristic B (v) corresponds to reference tone conversion characteristic of the present invention.
T′(v)=α×T(v)+(1−a)×B(v) (numeral 1)

As described above, in the present embodiment, by synthesizing the reference tone conversion characteristic B (v) and T (v) at a rate of α, it is possible to approximate the tone conversion characteristic T′ (v) to the reference tone conversion characteristic B (v) by a degree defined by the rate α. The tone conversion is applied to pixel value Pv of pixel P=(px, py) using the tone conversion characteristic T′ (v) to obtain T′ (Pv), and the obtained T′ (Pv) is set as the pixel value of pixel P=(px, py) after tone conversion. Therefore, in the space-variant tone conversion processing as shown in FIG. 4, the larger the value σ that represents the area size is, the smaller a degree at which the tone conversion characteristic varies depending on the pixel position becomes. Further, it is possible to adjust the level of influence of the space-variant tone conversion on the result of tone conversion processing by changing the value of α. For example, the smaller the value of α, the better the processing result can be brought close to a conversion result obtained according to the reference tone conversion characteristic irrespective of the pixel position.

The above processing converts the G-component input image G (x, y) of an RGB color image into a new image G′ (x, y). After that, known processing represented by the following (numeral 2) and (numeral 3) is applied to R-component input image R (x, y) of the RGB color image and B-component input image B (x, y) of the RGB color image to thereby obtain new R-component image R′ (x, y) and B-component image B′ (x, y). Finally, a color image consists of three components of R′ (x, y), G′ (x, y), and B′ (x, y) is output as a color image after tone conversion.
R′(x, y)=R(x, y)×G′(x, y)/G(x, y) (numeral 2)
B′(x, y)=B(x, y)×G′(x, y)/G(x, y) (numeral 3)

The recording processing means 170 applies compression processing to the output obtained as a result of the space-variant tone conversion processing performed by the sectional tone conversion processing section 152 to convert the output into a JPEG or TIFF color image and stores the image in the storage section 180. The above processing performed by the image pickup means 120, A/D conversion means 130, RGB processing means 140, tone conversion means 150, conversion characteristic determination means 160, and recording processing section 170 are executed by a CPU incorporated in the image pickup apparatus 100. More specifically, the CPU performs the above processing based on a processing program stored in a memory such as ROM while writing required data in a recording medium such as RAM appropriately.

The above processing may be performed by software installed in equipment separated from the image pickup apparatus 100. In this case, functions of the RGB processing means 140, tone conversion means 150, conversion characteristic determination means 160, and recording processing section 170 are realized by software installed in equipment separated from the image pickup apparatus 100 and an obtained result is stored in the storage means of the equipment.

With reference to FIG. 5, the flow of the processing performed by the above respective means will be described.

Firstly, in step S101, user's selection of image pickup condition (exposure correction condition or application or not application of camera shake prevention function) is received and the image pickup condition is determined. In step S102, image pickup operation is performed according to the image pickup condition determined in step S101. The image pickup condition according to which the image pickup operation has been performed is stored in a not shown storage means in the image pickup apparatus 100. The processing of step S102 is performed by the image pickup means 120. In step S103, an analog output signal from the image pickup means 120 obtained by the processing of step S102 is converted into a digital signal to generate image data of the image pickup time. The processing of step S103 is performed by the A/D conversion means 130. In step S104, color image data of three colors (B, G and R) is generated based on the output from the A/D conversion means 130 obtained in the step S103. The processing performed in the same as the processing performed by the RGB processing means 140. In step S105, with reference to the conversion characteristic selection table 161 and based on the image pickup condition (exposure correction condition or application or not application of camera shake prevention function) used at the image pickup time performed in step S102, tone conversion characteristic to be applied to the image pickup condition is determined. The processing performed in step S105 is the same as the processing performed by the conversion characteristic determination means 160.

In step S106, the tone conversion characteristic determined by the conversion characteristic determination means 160 in the processing of step S105 is used to apply collective tone conversion processing to pixel values of respective pixels in the image data obtained from the RGB processing means 140. The processing of step S106 is the same as the processing performed by the collective tone conversion processing section 151. In step S107, the abovementioned space-variant tone conversion processing is applied to the image data that has been processed 151 in step S106. The processing of step S107 is the same as the processing performed by the sectional tone conversion processing section 152. Finally, in step S108, compression processing is applied to the image data that has been processed in step S107 to obtain a JPEG or TIFF color image data, and the resultant image data is stored in the storage section 180.

As described above, in the present embodiment, not only that the space-variant tone conversion is realized, but also that the common tone conversion characteristic corresponding to image pickup condition is used to perform image correction before the space-variant tone conversion processing. As a result, the user can obtain a satisfactory image. In particular, tone conversion can be performed using the tone conversion characteristic corresponding to the exposure correction condition or tone conversion characteristic that corrects underexposure caused due to restriction on shutter speed before the space-variant tone conversion processing, so that it is possible to further increase the effect of the tone conversion corresponding to the image pickup condition.

### Second Embodiment

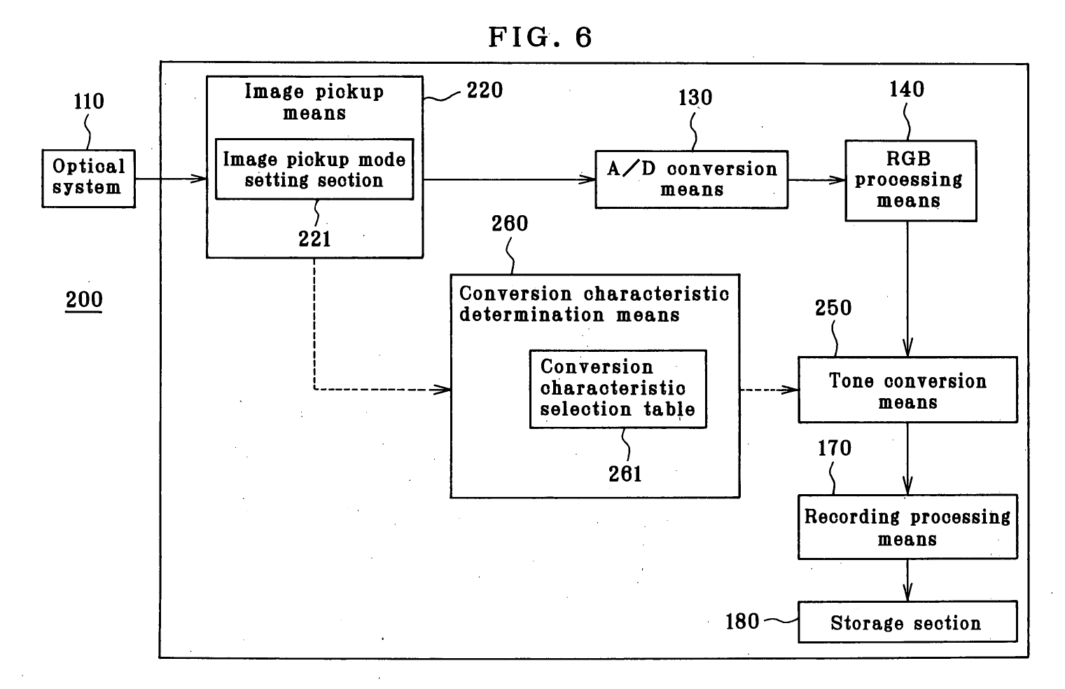

An image pickup apparatus according to a second embodiment of the present invention will be described with reference to FIG. 6 to FIG. 10. As in the case of the first embodiment, an image pickup apparatus exemplified here may be a digital still camera, a microscope, or an image pickup apparatus connected to an endoscope.

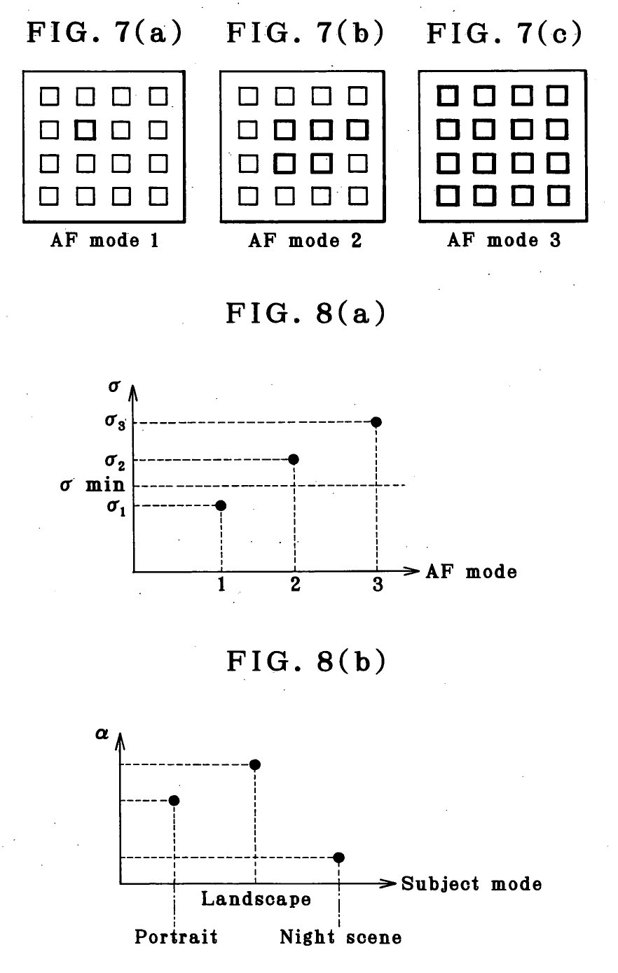

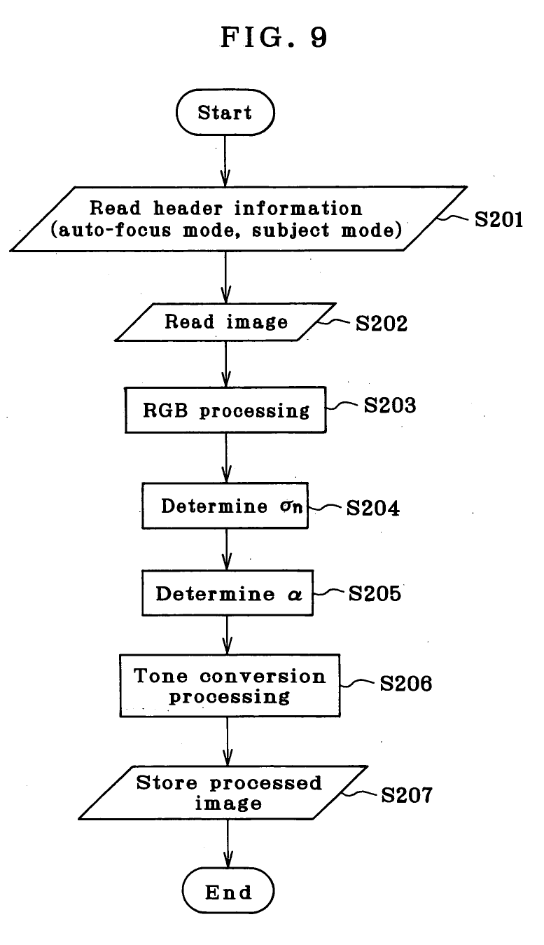

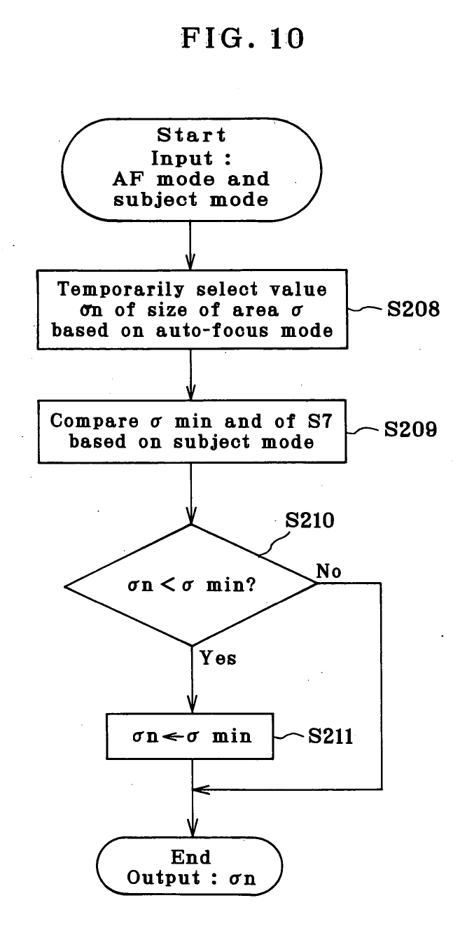

FIG. 6 is a block diagram showing a functional configuration of an image processing apparatus 200. FIG. 7 is a view for explaining the respective modes of an auto-focus function. FIG. 8 is a view for explaining values σ and α relative to respective image pickup conditions. FIGS. 9 and 10 are views for explaining the flow of processing in the present embodiment. In this embodiment, the same terms and reference numerals as the first embodiment are used for the components which are common to the first embodiment, and the detailed description thereof is omitted.

As shown in FIG. 6, the image pickup apparatus 200 according to the second embodiment includes the optical system 110, image pickup means 220, A/D conversion means 130, RGB processing means 140, tone conversion means 250, conversion characteristic determination means 260, recording processing means 170, and storage section 180. That is, the optical system 110, A/D conversion means 130, RGB processing means 140, recording processing means 170, and storage section 180 are the same as those in the first embodiment; whereas image pickup means 220, tone conversion means 250, and conversion characteristic determination means 260, which are different from those in the first embodiment, characterize the second embodiment.

The image pickup means 220 includes an image pickup device such as a CCD or CMOS. In picking up a subject image, the image pickup means 220 converts the subject image focused by the optical system 110 into an electrical image signal. The image pickup means 220 further includes an image pickup mode setting section 221 and a user interface (not shown) for a user to select subject mode and auto-focus mode. The image pickup mode setting section 221 receives user's operation through the user interface and sets an image pickup condition such as subject mode or auto-focus mode. Examples of the subject mode include portrait mode, landscape mode, and night scene mode. Examples of the auto-focus mode include Spot-AF and Multi-AF. The image pickup mode setting section 221 stores the set image pickup condition (subject mode or auto-focus mode). FIG. 7 is a view for explaining the Spot-AF and Multi-AF.

AF mode 1 of FIG. 7(a) explains the Spot-AF, where focusing is performed with reference to the distance to a subject existing in a narrow area in the vicinity of the center (“center” is merely an example and the subject to be focused on may be positioned at any location within the screen, or function that can select, to some extent, the location to be focused on may be implemented) of the screen. AF mode 2 of FIG. 7(b) explains the Multi-AF, where focusing is performed with reference to the distances to a plurality of subjects in the vicinity of the center of the screen. AF mode 3 of FIG. 7(c) also explains the Multi-AF, where focusing is performed with reference to the distances to a plurality of subjects spread across a wider area than in the case of FIG. 7(b).

That is, after the image pickup apparatus 200 has received user's selection of the image pickup condition (subject mode or auto-focus mode) and user's operation of a shutter button (not shown) of the image pickup apparatus 200, the optical image of a subject is focused on the image pickup device (CCD or CMOS) of the image pickup means 220 by the optical system 110, and the selected image pickup condition (subject mode or auto-focus mode) is stored in the image pickup mode setting section 221. After allowing the image pickup device to convert the optical image into an electrical signal, the image pickup means 220 outputs the electrical signal to the A/D conversion means 130. The A/D conversion means 130 converts the electrical signal into digital data and outputs it to the RGB processing means 140. The RGB processing means 140 applies processing to the input digital data to generate image data of three colors (R, G, and B) and outputs it to the tone conversion means 250.

The tone conversion means 250 applies the space-variant tone conversion processing as described in the first embodiment with reference to FIG. 4 to the image data output from the RGB processing means 140. In the present embodiment, value σ of the size of the area around pixel P=(px, py) and synthesis ratio α relative to the reference conversion characteristic are determined by the conversion characteristic determination means 260. The conversion characteristic determination means 260 has a conversion characteristic selection table 261, in which correspondences between the image pickup conditions and value σ of the size of the area to be applied to the image pickup conditions, and those between the image pickup conditions and synthesis rate α are stored. Assuming that the image pickup condition includes the abovementioned subject mode and auto-focus mode, the following correspondences are stored in the conversion characteristic selection table 261 of the conversion characteristic determination means 260.

That is, the correspondences between the auto-focus mode and value σ are set in the conversion characteristic selection table 261 such that as the image pickup condition is shifted from “AF mode 3” of FIG. 7(c) to “AF mode 1” of FIG. 7(a), that is, as the area in the screen that a subject or subjects whose distance from the apparatus is to be referred to exist becomes narrower, the value of σ is reduced from default value σ3 to σ1, as shown in FIG. 8(a). As described above, in the present embodiment, in the case where the user specifies a particular part of the subject in a more explicit manner like the case of the Spot-AF, the value of σ of the size of the area is reduced such that optimal local contrast can be achieved to thereby increase a degree at which the tone conversion characteristic varies depending on the pixel position. As a result, user's intention can appropriately be reflected in the image quality.

Similar correspondences between subject mode and synthesis rate α are stored, as shown in, for example, FIG. 8(b). For example, when the space-variant tone conversion processing is applied to an image of the night scene, entire image becomes too bright to spoil the atmosphere. To cope with the above problem, the value of α is reduced as shown in FIG. 8(b). As described above, in the present embodiment, it is possible to obtain image quality that matches the user's tastes more suitably by adjusting the level of influence of the space-variant tone conversion on the result of tone conversion processing depending on the subject type. Further, in order to prevent the image quality from being lost due to excessively strong contrast, the conversion characteristic determination means 260 stores, as a safety level value of σ, minimum value σ min of the value σ of the area size depending on the subject mode. That is, the definition of the minimum value σ min of the value σ of the area size sets the upper limit of a degree at which the tone conversion characteristic varies depending on the pixel position.

For example, even if a value σ1 of the size of the area has been stored in relation to “AF mode 1”, the value σ1 is not selected but a value σ min larger than the al is selected in the case where portrait mode has been selected by the user. That is, different values are set as the value σ min depending on the types of the subject mode. As described above, by defining the minimum value σ min of the value σ of the area size to set the upper limit of a degree at which the tone conversion characteristic varies depending on the pixel position, it is possible to prevent the image quality from being lost due to excessively strong contrast. For example, in the case where image pickup operation is performed with focus placed on, for example, a person in portrait mode, it is possible to prevent his or her face from looking evil due to strong contrast.

The conversion characteristic determination means 260 acquires information related to auto-focus mode from the image pickup mode setting section 221 prior to the space-variant tone conversion processing performed in the tone conversion means 250 and refers to the conversion characteristic selection table 261 to temporarily determine the value σ of the size of the area to be applied to the set type of the auto-focus mode. After that, the conversion characteristic determination means 260 acquires information related to subject mode from the image pickup mode setting section 221. The conversion characteristic determination means 260 then compares the value σ min that has been set depending on the type of the subject mode and the temporarily determined value σ of the size of the area. In the case where the temporarily determined value σ of the size of the area is larger than the value σ min that has been set depending on the type of the subject mode, the conversion characteristic determination means 260 eventually sets the temporarily determined value σ of the size of the area as the value σ of the size of the area.

On the other hand, in the case where the temporarily determined value σ of the size of the area is smaller than the value σ min that has been set depending on the type of the subject mode, the conversion characteristic determination means 260 eventually sets the value σ min as the value σ of the size of the area. That is, the conversion characteristic determination means 260 determines the value σ of the size of the area so as to reduce a degree at which the tone conversion characteristic varies depending on the pixel position. Since the value of σ min is set depending on the type of the subject mode as described above, it is possible to change a degree of local contrast depending on the type of the subject mode. As a result, user's intention can appropriately be reflected in the image quality.

Further, the conversion characteristic determination means 260 refers to the conversion characteristic selection table 261 based on the information related to the subject mode that has been acquired from the image pickup mode setting section 221 to thereby set the value of synthesis rate α. The conversion characteristic determination means 260 then instructs the tone conversion means 250 to perform tone conversion processing using the eventually set values of σ and α. The tone conversion means 250 uses the values of σ and α designated by the conversion characteristic determination means 260 to perform the abovementioned space-variant tone conversion processing. That is, the conversion characteristic determination means 260 determines the values of σ and α depending on the image pickup condition, and tone conversion means 250 performs space-variant tone conversion processing based on the determined values of σ and α.

As described above, in the present embodiment, in the case where focusing is performed on the narrower area like the case of the Spot-AF, as the area to be focused on becomes narrower, a degree at which the tone conversion characteristic differs becomes large between the focused area and other area. That is, the use of the value σ of the size of the area as a parameter for adjusting local contrast in the space-variant tone conversion processing simplifies the correspondence between the area (see FIG. 7) in the image to be referred to at the actual time of autofocusing and image conversion processing. As a result, user's intention can appropriately be reflected in the image quality. Further, it is possible to obtain image quality that matches the user's tastes more suitably by adjusting the level of influence of the space-variant tone conversion on the result of tone conversion processing depending on the subject mode.

The recording processing means 170 applies compression processing to the output obtained as a result of the space-variant tone conversion processing performed by the tone conversion means 250 to convert the output into a JPEG or TIFF color image and stores the image in the storage section 180. The above processing performed by the image pickup means 220, A/D conversion means 130, RGB processing means 140, tone conversion means 250, conversion characteristic determination means 260, and recording processing means 170 are executed by a CPU incorporated in the image pickup apparatus 200. More specifically, the CPU performs the above processing based on a processing program stored in a memory such as ROM while writing required data in a recording medium such as RAM appropriately.

The above processing may be performed by software installed in equipment separated from the image pickup apparatus 200. In this case, functions of the RGB processing means 140, tone conversion means 250, conversion characteristic determination means 260, and recording processing means 170 are realized by software installed in equipment separated from the image pickup apparatus 200 and an obtained result is stored in the storage means of the equipment, as shown in FIGS. 9 and 10.

As shown in FIG. 9, in step S201, firstly header information of a RAW data file is read out and information related to subject mode or auto-focus mode set at the image pickup time is acquired. The “RAW data file” is a data file obtained by adding information including image pickup condition to RAW data of the image pickup time as a header. Subsequently, in step S202, the RAW data is read out. In step S203, RGB processing is applied to the entire RAW data that has been read out to generate color image data of three colors (R, G, B). The obtained color image data is stored in a previously allocated buffer. The RGB processing in step S203 is the same as the processing performed by the RGB processing means 140.

After that, tone conversion processing is applied to the color image data in the buffer. Before the tone conversion processing, a value of σn of the size of the area is determined as a parameter of the tone conversion in step S204. The processing in step S204 is, as shown in FIG. 10, the same as the processing performed by the conversion characteristic determination means 260. That is, the value an of the size of the area is temporarily determined depending on the type of the auto-focus mode (step S208), and the σ min and temporarily determined value an of the size of the area are compared to each other based on the set subject mode (step S209). If σn is smaller than σ min (Yes in step S210), σ min is eventually set in place of σn (step S211).

After completion of the processing in step S204 shown in FIG. 9, in step S205, the value of synthesis rate α is determined as a parameter of the tone conversion. The processing in step S205 is the same as the processing performed by the conversion characteristic determination means 260. Next, in step S206, tone conversion processing is performed. The processing in step S206 is the same as the processing performed by the tone conversion means 250. Finally, in step S207, an output obtained as a result of the tone conversion processing is stored.

The auto-focus mode has been taken as an example of the image pickup conditions in the second embodiment described above. However, the same processing as in the case of the auto-focus mode can be applied to other image pickup conditions in which a degree at which a particular part of the subject is designated in an explicit manner varies. For example, auto-exposure mode including Spot-AE, Multi-AE, and the like can be set as the image pickup condition. The Spot-AE is a mode where the image pickup apparatus determines exposure with reference to information (brightness and the like) of a subject existing in the vicinity of the center (“center” is merely an example and the subject to be focused on may be positioned at any location within the screen, or function that can select, to some extent, the location to be focused on may be implemented) of the screen. The Multi-AE is a mode where exposure is performed with reference to information (brightness and the like) of a plurality of subjects in the vicinity of the center of the screen.

### Third Embodiment

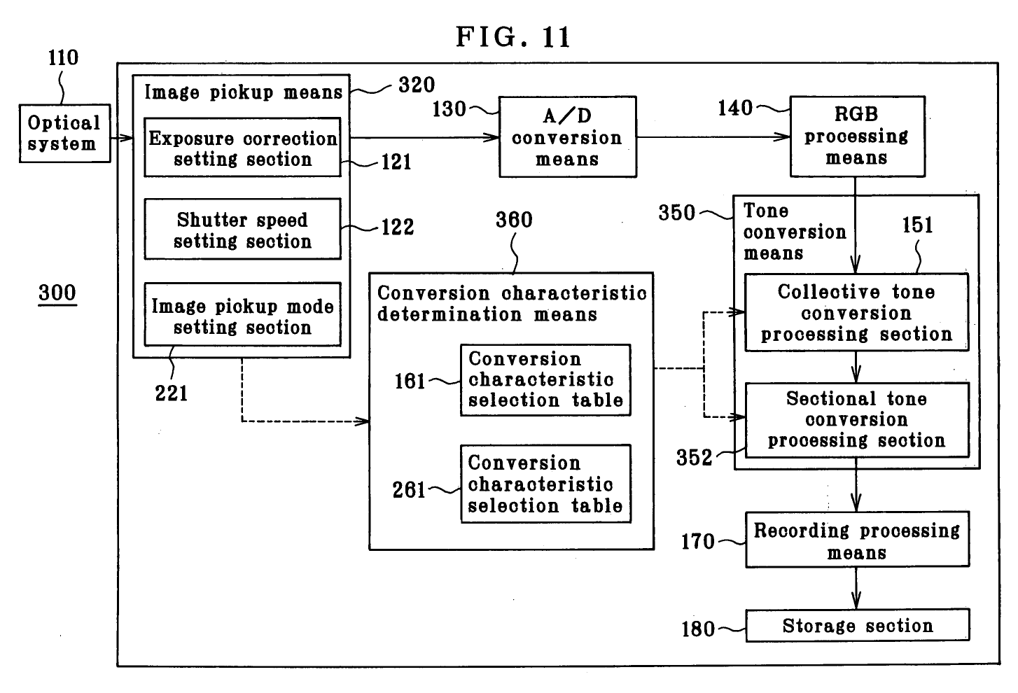

An image pickup apparatus according to a third embodiment of the present invention will be described with reference to FIG. 11. As in the case of the first embodiment, an image pickup apparatus exemplified here may be a digital still camera, a microscope, or an image pickup apparatus connected to an endoscope. FIG. 11 is a block diagram showing a functional configuration of an image processing apparatus 300. In this embodiment, the same terms and reference numerals as the first and second embodiments are used for the components which are common to the first and second embodiments, and the detailed description thereof is omitted.

As shown in FIG. 11, the image pickup apparatus 300 according to the third embodiment includes the optical system 110, image pickup means 320, A/D conversion means 130, RGB processing means 140, tone conversion means 350, conversion characteristic determination means 360, recording processing means 170, and storage section 180. That is, the optical system 110, A/D conversion means 130, RGB processing means 140, recording processing means 170, and storage section 180 are the same as those in the first and second embodiments; whereas image pickup means 320, tone conversion means 350, and conversion characteristic determination means 360, which are different from those in the first and second embodiments, characterize the third embodiment.

The image pickup means 320 includes an image pickup device such as a CCD or CMOS. In picking up a subject image, the image pickup means 320 converts the subject image focused by the optical system 110 into an electrical image signal. The image pickup means 320 further includes an exposure correction setting section 121, shutter speed setting section 122, image pickup mode setting section 221, and user interface (not shown) for a user to select exposure correction condition, application or not application of camera shake prevention function, subject mode and auto-focus mode. The exposure correction setting section 121, shutter speed setting section 122, and image pickup mode setting section 221 receive user's operation through the user interface and set image pickup conditions such as exposure correction condition, application or not application of camera shake prevention function, subject mode and auto-focus mode.

That is, after the image pickup apparatus 300 has received user's selection of the image pickup condition (exposure correction condition, application or not application of camera shake prevention function, subject mode and auto-focus mode) and user's operation of a shutter button (not shown) of the image pickup apparatus 300, the optical image of a subject is focused on the image pickup device (CCD or CMOS) of the image pickup means 320 by the optical system 110, and the selected image pickup conditions are stored in the exposure correction setting section 121, shutter speed setting section 122, and image pickup mode setting section 221. After allowing the image pickup device to convert the optical image into an electrical signal, the image pickup means 320 outputs the electrical signal to the A/D conversion means 130.

The conversion characteristic determination means 360 has a conversion characteristic selection table 161 and conversion characteristic selection table 261. The tone conversion means 350 has a collective tone conversion processing section 151 and a sectional tone conversion processing section 352. The collective tone conversion processing section 151 corresponds to a first conversion processing section of the present invention, and sectional tone conversion processing section 352 corresponds to a second conversion processing section of the present invention. The conversion characteristic determination means 360 uses the conversion characteristic selection table 161 to determine tone conversion characteristic corresponding to the set image pickup condition as in the case of the first embodiment. The collective tone conversion processing section 151 of the tone conversion means 350 applies tone conversion processing to the image data output from the RGB processing means 140 based on the determined tone conversion characteristic.

Further, the conversion characteristic determination means 360 uses the conversion characteristic selection table 261 to determine values of a and a like the conversion characteristic determination means 260 of the second embodiment. The sectional tone conversion processing section 352 of the tone conversion means 350 applies tone conversion processing to the image data output from the collective tone conversion processing section 151 based on the determined values of σ and α. The tone conversion processing performed by the sectional tone conversion processing section 352 is the same as the space-variant tone conversion processing performed by the tone conversion means 250 which has been described in the second embodiment. The recording processing means 170 applies compression processing to the output obtained as a result of the space-variant tone conversion processing performed by the sectional tone conversion processing section 352 to convert the output into a JPEG or TIFF color image and stores the image in the storage section 180.

In the present embodiment, the conversion characteristic determination means 360 may have another conversion characteristic selection table serving as an alternative to the conversion characteristic selection tables 161 and 261. In the another conversion characteristic selection table, combinations of image pickup conditions (exposure correction condition, application or not application of camera shake prevention function, subject mode, auto-focus mode) and combinations of tone conversion characteristics to be applied to the tone conversion processing of the collective tone conversion processing section 151 and values of a and a to be applied to the tone conversion processing of the sectional tone conversion processing section 352 are related to each other.

In this case, the conversion characteristic determination means 360 refers to the another conversion characteristic selection table serving as an alternative to the conversion characteristic selection tables 161 and 261 and determines the tone conversion characteristic to be applied to the tone conversion processing of the collective tone conversion processing section 151 and values of σ and α to be applied to the tone conversion processing of the sectional tone conversion processing section 352 based on the combinations of the image pickup conditions of the image pickup time that have been stored in the exposure correction setting section 121, shutter speed setting section 122, and image pickup mode setting section 221. After that, the collective tone conversion processing section 151 and sectional tone conversion processing section 152 uses the determined tone conversion characteristic to perform tone conversion processing. The above processing performed by the image pickup means 320, A/D conversion means 130, RGB processing means 140, tone conversion means 350, conversion characteristic determination means 360, and recording processing section 170 are executed by a CPU incorporated in-the image pickup apparatus 300. More specifically, the CPU performs the above processing based on a processing program stored in a memory such as ROM while writing required data in a recording medium such as RAM appropriately.

As described above, according to the present invention, image conversion can be performed using different tone conversion characteristics depending on the pixel position. Further, the tone conversion characteristic can be determined depending on the image pickup condition. Therefore, an image pickup apparatus having high tone conversion capability can be provided.

### INDUSTRIAL APPLICABILITY

As described above, according to the present invention, an image pickup apparatus having high tone conversion capability can be provided.

1. An image pickup apparatus characterized by comprising:
image pickup means for acquiring image data of a subject;
tone conversion means for applying tone conversion processing to the image data acquired by the image pickup means using different tone conversion characteristics depending on the pixel position; and
conversion characteristic determination means for determining the tone conversion characteristic depending on an image pickup condition that has been set in the image pickup means for acquisition of the digital image data.

2. The image pickup apparatus according to claim 1, characterized in that
the conversion characteristic determination means determines a degree at which the tone conversion characteristic for each pixel varies depending on the pixel position based on the image pickup condition that has been set for acquisition of the digital image data.

3. The image pickup apparatus according to claim 2, characterized in that
the image pickup condition includes conditions related to auto-focus, and
the conversion characteristic determination means determines a degree at which the tone conversion characteristic for each pixel varies depending on the pixel position based on the conditions related to auto-focus.

4. The image pickup apparatus according to claim 3, characterized in that
the conversion characteristic determination means determines the tone conversion characteristic such that a degree at which the tone conversion characteristic for each pixel differs becomes large depending on the pixel position as the area to be focused on becomes narrower in the conditions related to auto-focus.

5. The image pickup apparatus according to claim 2, characterized in that
the image pickup condition includes various types of subject modes,
the image pickup means picks up an image of a subject in one subject mode that has been designated from the outside to acquire the image data, and
the conversion characteristic determination means determines a degree at which the tone conversion characteristic for each pixel varies depending on the pixel position based on the one subject mode that has been designated from the outside.

6. The image pickup apparatus according to claim 5, characterized in that
the conversion characteristic determination means sets the upper limit of a degree at which the tone conversion characteristic for each pixel varies depending on the pixel position based on the type of the subject mode and determines a degree at which the tone conversion characteristic for each pixel varies depending on the pixel position based on the upper limit.

7. The image pickup apparatus according to claim 2, characterized in that
the tone conversion means calculates the tone conversion characteristic based on a histogram that represents the distribution of pixel values of pixels to be subjected to the tone conversion processing and pixels existing in a predetermined range around the target pixels, and
the conversion characteristic determination means determines the size of the predetermined range to thereby determine a degree at which the tone conversion characteristic for each pixel varies depending on the pixel position.

8. The image pickup apparatus according to claim 3, characterized in that
the tone conversion means calculates the tone conversion characteristic based on a histogram that represents the distribution of pixel values of pixels to be subjected to the tone conversion processing and pixels existing in a predetermined range around the target pixels, and
the conversion characteristic determination means determines the size of the predetermined range to thereby determine a degree at which the tone conversion characteristic for each pixel varies depending on the pixel position.

9. The image pickup apparatus according to claim 5, characterized in that
the tone conversion means calculates the tone conversion characteristic based on a histogram that represents the distribution of pixel values of pixels to be subjected to the tone conversion processing and pixels existing in a predetermined range around the target pixels, and
the conversion characteristic determination means determines the size of the predetermined range to thereby determine a degree at which the tone conversion characteristic for each pixel varies depending on the pixel position.

10. The image pickup apparatus according to claim 1, characterized in that
the tone conversion means has a function of approximating the tone conversion characteristic to reference tone conversion characteristic that has been previously defined, and
the conversion characteristic determination means determines a degree at which the tone conversion characteristic is approximated to the reference tone conversion characteristic depending on the image pickup condition to thereby determine the tone conversion characteristic.

11. The image pickup apparatus according to claim 2, characterized in that
the tone conversion means has a function of approximating the tone conversion characteristic to reference tone conversion characteristic that has been previously defined, and
the conversion characteristic determination means determines a degree at which the tone conversion characteristic is approximated to the reference tone conversion characteristic depending on the image pickup condition to thereby determine the tone conversion characteristic.

12. The image pickup apparatus according to claim 3, characterized in that
the tone conversion means has a function of approximating the tone conversion characteristic to reference tone conversion characteristic that has been previously defined, and
the conversion characteristic determination means determines a degree at which the tone conversion characteristic is approximated to the reference tone conversion characteristic depending on the image pickup condition to thereby determine the tone conversion characteristic.

13. The image pickup apparatus according to claim 5, characterized in that
the tone conversion means has a function of approximating the tone conversion characteristic to reference tone conversion characteristic that has been previously defined, and
the conversion characteristic determination means determines a degree at which the tone conversion characteristic is approximated to the reference tone conversion characteristic depending on the image pickup condition to thereby determine the tone conversion characteristic.

14. The image pickup apparatus according to claim 1, characterized in that
the tone conversion means includes a first conversion processing section that applies tone conversion processing to the image data and a second conversion processing section that applies tone conversion processing corresponding to the pixel position to an output of the first conversion processing section, and
the conversion characteristic determination means determines tone conversion characteristic to be used in tone conversion processing performed by the first conversion processing section depending on the image pickup condition.

15. The image pickup apparatus according to claim 14, characterized in that
the first conversion processing section performs tone conversion processing for respective pixels constituting the subject image using common tone conversion characteristic, and
the conversion characteristic determination means changes the common tone conversion characteristic set in the first conversion processing section depending on the image pickup condition.

16. The image pickup apparatus according to claim 15, characterized in that
the image pickup condition includes an exposure correction condition that defines an exposure correction level, and
the conversion characteristic determination means changes the tone conversion characteristic depending on the exposure correction condition.

17. The image pickup apparatus according to claim 15, characterized in that
the image pickup condition includes an exposure condition which is based on restriction on the shutter speed, and
the conversion characteristic determination means changes the tone conversion characteristic depending on the exposure condition.

18. The image pickup apparatus according to claim 1, characterized in that
the image pickup condition includes an exposure correction condition that defines an exposure correction level, and
the conversion characteristic determination means changes the tone conversion characteristic depending on the exposure correction condition.

19. The image pickup apparatus according to claim 1, characterized in that
the image pickup condition includes an exposure condition which is based on restriction on the shutter speed, and
the conversion characteristic determination means changes the tone conversion characteristic depending on the exposure condition.
